(19) United States
(12) Patent Application Publication
(10) Pub. No.: US 2025/0293022 A1
(43) Pub. Date: Sep. 18, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventor: Kazuki NONOMURA, Toyama-shi (JP)

(73) Assignee: KOKUSAI ELECTRIC CORPORATION, Tokyo (JP)

(21) Appl. No.: 19/064,839

(22) Filed: Feb. 27, 2025

(30) Foreign Application Priority Data
Mar. 12, 2024 (JP) 2024-038400

(51) Int. Cl. H01L 21/02; C23C 16/04; C23C 16/455; C23C 16/52; H01J 37/32; H01L 21/311

(52) U.S. Cl. CPC H01L 21/02312; C23C 16/04; C23C 16/4554; C23C 16/45544; C23C 16/52; H01J 37/32449; H01L 21/0228; H01L 21/31116

(57) ABSTRACT

There is provided a technique that includes: performing a first step and a second step a predetermined number of times, wherein the first step includes performing a predetermined number of times: (a1) supplying a first modifying gas to the substrate to form a first modified layer on at least a portion of the substrate; and (a2) supplying a first removal gas to the substrate to remove a portion of the first modified layer from the substrate, and wherein the second step includes performing, after the first step, a predetermined number of times: (b1) supplying a process gas to the substrate to preferentially process an area where the first modified layer is not formed over an area where the first modified layer is present; and (b2) supplying a reactant gas to the substrate.

### CROSS-REFERENCE TO RELATED APPLICATION

This application is based upon and claims the benefit of priority from Japanese Patent Application No. 2024-038400, filed on Mar. 12, 2024, the entire contents of which are incorporated herein by reference.

### TECHNICAL FIELD

The present disclosure relates to a method of processing a substrate, a method of manufacturing a semiconductor device, a substrate processing apparatus, and a recording medium.

### BACKGROUND

As a process of processing a substrate (a process of manufacturing a semiconductor device), a film may be formed on a surface of a substrate by using a substance that inhibits adsorption of other substances to the substrate.

### SUMMARY

Some embodiments of the present disclosure provide a technique capable of controlling areas of a substrate where processing is likely to progress and areas of the substrate where the processing is inhibited.

According to embodiments of the present disclosure, there is provided a technique that includes: performing a first step and a second step a predetermined number of times, wherein the first step includes performing a predetermined number of times: (a1) supplying a first modifying gas to the substrate to form a first modified layer on at least a portion of the substrate; and (a2) supplying a first removal gas to the substrate to remove a portion of the first modified layer from the substrate, and wherein the second step includes performing, after the first step, a predetermined number of times: (b1) supplying a process gas to the substrate to preferentially process an area where the first modified layer is not formed over an area where the first modified layer is present; and (b2) supplying a reactant gas to the substrate.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus, illustrating a process furnace in a vertical cross-sectional view.

FIG. 2 is a schematic configuration diagram of the vertical process furnace of the substrate processing apparatus, illustrating an example of a cross-sectional view of the process furnace taken along line A-A in FIG. 1.

FIG. 3 is a schematic configuration diagram of a controller of the substrate processing apparatus, illustrating a control system of the controller in a block diagram.

FIG. 4A is a diagram illustrating a process sequence according to embodiments of the present disclosure.

FIG. 4B is a diagram illustrating an example of a procedure in step S10.

FIG. 4C is a diagram illustrating an example of a procedure in step S12.

FIGS. 5A to 51 are schematic diagrams of a cross-sectional portion of a surface of a wafer obtained by executing each procedure of the process sequence of FIGS. 4A to 4C.

FIG. 6 is a schematic configuration diagram of a vertical process furnace of the substrate processing apparatus, illustrating an example of a cross-sectional view of the process furnace taken along line A-A in FIG. 1, in a case where a gas is activated by plasma.

FIG. 7A is a diagram illustrating an example of a process sequence in Modification 1.

FIG. 7B is a diagram illustrating an example of step S30 in Modification 1.

FIGS. 8A to 8I are diagrams schematically illustrating a cross-sectional portion of a surface of the wafer after steps S10-1, S10-2, and S10-3 are performed, respectively, in a case where modification 1 is performed using patterns (1) to (3) in which at least part of processing conditions for each procedure differ.

FIG. 9A is a diagram illustrating a process sequence in Modification 2.

FIG. 9B is a diagram illustrating an example of a procedure in step S40.

FIG. 10 is a diagram illustrating a process sequence in Modification 3.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### EMBODIMENTS OF PRESENT DISCLOSURE

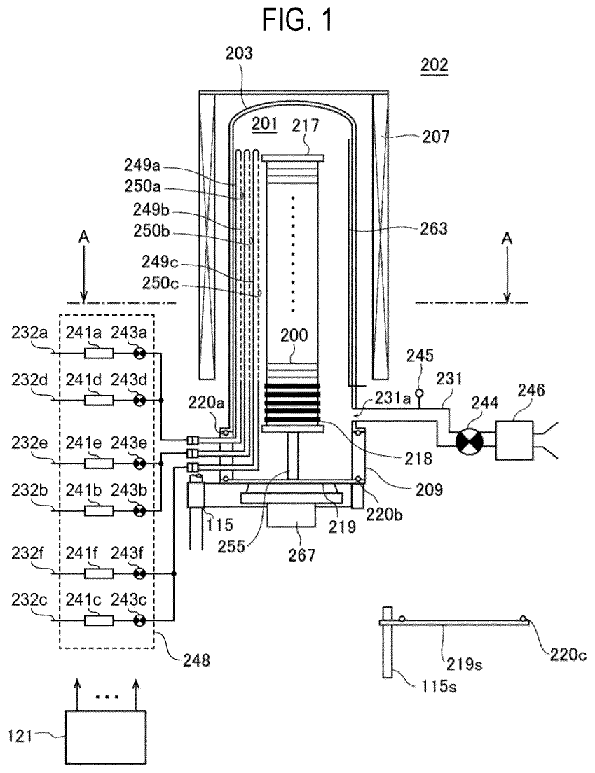

Hereinafter, embodiments of the present disclosure are described mainly with reference to FIGS. 1 to 51. In addition, the drawings used in the following description are schematic, and dimensional relationships between respective components and the proportions of respective components illustrated in the drawings may not correspond to those in reality. Further, the dimensional relationships between respective elements and the proportions of respective elements may not match among multiple drawings.

### (1) Configuration of Substrate Processing Apparatus

As illustrated in FIG. 1, a process furnace 202 includes a heater 207. The heater 207 also functions as an activator (exciter) that activates (excites) gases with heat.

A reaction tube 203 is disposed inside the heater 207. A manifold 209 is disposed below the reaction tube 203, and an O-ring 220a is provided between the manifold 209 and the reaction tube 203. A process container (reaction container) mainly includes the reaction tube 203 and the manifold 209. A process chamber 201 is formed in an interior of the process container. The process chamber 201 is configured to be capable of accommodating a wafer 200 serving as a substrate. The wafer 200 is processed within the process chamber 201.

Nozzles 249a to 249c are installed respectively inside the process chamber 201. Gas supply pipes 232a to 232c are connected to the nozzles 249a to 249c, respectively.

The gas supply pipes 232a to 232c are installed, respectively, with mass flow controllers (MFCs) 241a to 241c, which serve as flow-rate controllers (flow-rate control parts), and valves 243a to 243c, which serve as opening/closing valves, in order from an upstream of a gas flow. A gas supply pipe 232d is connected to the gas supply pipe 232a at a downstream of the valve 243a. A gas supply pipe 232e is connected to the gas supply pipe 232b at a downstream of the valve 243b. A gas supply pipe 232f is connected to the gas supply pipe 232c at a downstream of the valve 243c. The gas supply pipes 232d to 232f are provided, respectively, with MFCs 241d to 241f and valves 243d to 243f in order from an upstream of a gas flow.

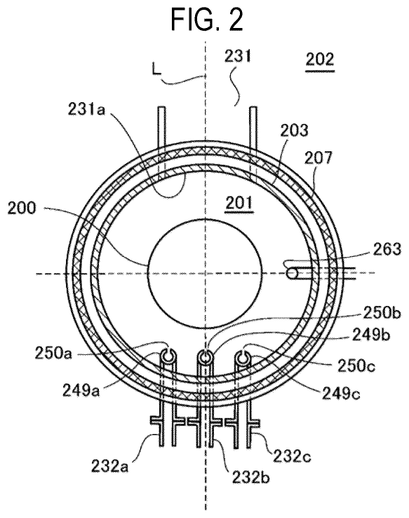

As illustrated in FIG. 2, the nozzles 249a to 249c are installed respectively in a space between an inner wall of the reaction tube 203 and the wafer 200. The nozzles 249a and 249c are disposed on both sides of a straight line L passing through a center of the nozzle 249b and an exhaust port 231a. Gas supply holes 250a to 250c that supply gases toward the wafer 200 are formed, respectively, on the nozzles 249a to 249c. The gas supply holes 250a to 250c are formed in plural from a bottom to a top of the respective nozzles 249a to 249c.

A first modifying gas is supplied into the process chamber 201 through the gas supply pipe 232a, MFC 241a, valve 243a, and nozzle 249a. The first modifying gas in the present embodiments is a gas that inhibits a process gas from being adsorbed on the wafer 200.

A process gas is supplied into the process chamber 201 through the gas supply pipe 232b, MFC 241b, valve 243b, and nozzle 249b. The process gas in the present embodiments is a precursor gas that forms a process layer 152 for reacting with a reactant gas to create (form) a desired film.

A first removal gas and a reactant gas are supplied into the process chamber 201 through the gas supply pipe 232c, MFC 241c, valve 243c, and nozzle 249c. The first removal gas is a gas that removes a portion of a first modified layer 150 formed by the first modifying gas. The reactant gas is a gas that reacts with the process layer 152 formed by the process gas to create (form) a desired film (first layer 154).

An inert gas is supplied into the process chamber 201 through the respective gas supply pipes 232d to 232f, MFCs 241d to 241f, valves 243d to 243f, gas supply pipes 232a to 232c, and nozzles 249a to 249c. The inert gas acts as a purge gas, a carrier gas, a dilution gas, and others.

A first modifying gas supply system mainly includes the gas supply pipe 232a, MFC 241a, and valve 243a. A process gas supply system mainly includes the gas supply pipe 232b, MFC 241b, and valve 243b. A first removal gas supply system and a reactant gas supply system mainly include the gas supply pipe 232c, MFC 241c, and valve 243c. In other words, the gas supply pipe 232c, MFC 241c, and valve 243c serve as both the first removal gas supply system and the reactant gas supply system. In addition, for example, the same configuration as the gas supply pipe 232c, MFC 241c, and valve 243c may be prepared to make the first removal gas supply system and the reactant gas supply system independent of each other. An inert gas supply system mainly includes the gas supply pipes 232d to 232f, MFCs 241d to 241f, and valves 243d to 243f. The nozzles connected to the gas supply pipes constituting the various supply systems described above may be included, respectively, in those supply systems.

Any of or the entire various supply systems described above may be configured as an integrated supply system 248 in which the valves 243a to 243f, MFCs 241a to 241f, and others are integrated. The integrated supply system 248 is connected to each of the gas supply pipes 232a to 232f, and is configured to allow the supply operations of various substances (various gases) into the gas supply pipes 232a to 232f such as the opening/closing operations of the valves 243a to 243f and the flow-rate regulation operations by the MFCs 241a to 241f to be controlled by a controller 121 to be described later.

The exhaust port 231a is formed at a lower side of a sidewall of the reaction tube 203 and is connected to an exhaust pipe 231 to exhaust the atmosphere in the process chamber 201. The exhaust pipe 231 is connected to a vacuum pump 246, which serves as a vacuum exhauster, through a pressure sensor 245, which serves as a pressure detector that detects an internal pressure of the process chamber 201, and an auto pressure controller (APC) valve 244, which serves as a pressure regulator. The APC valve 244 may perform or stop vacuum-exhaust in the process chamber 201 by opening and closing the valve while the vacuum pump 246 is operating. The APC valve 244 is further configured to be capable of regulating the internal pressure of the process chamber 201 by adjusting a valve opening degree based on pressure information detected by the pressure sensor 245 while the vacuum pump 246 is operating. An exhaust system mainly includes the exhaust pipe 231, APC valve 244, and pressure sensor 245. The vacuum pump 246 may also be considered as included in the exhaust system.

A seal cap 219 is installed below the manifold 209. An O-ring 220b is provided on an upper surface of the seal cap 219. A rotator 267 is installed below the seal cap 219. A rotating shaft 255 of the rotator 267 passes through the seal cap 219 and is connected to a boat 217. The rotator 267 is configured to rotate the wafer 200 by rotating the boat 217. A boat elevator 115 is configured as a transfer apparatus (transfer mechanism) that loads and unloads (transfers) the wafer 200 into and out of the process chamber 201 by moving the seal cap 219 up and down.

A shutter 219s is installed below the manifold 209 and is capable of airtightly closing an opening at a lower end of the manifold 209 in a state where the boat 217 is unloaded out of the process chamber 201. An O-ring 220c is provided on an upper surface of the shutter 219s. The opening/closing operation (such as elevating and rotating operations) of the shutter 219s is controlled by a shutter opening/closing mechanism 115s.

The boat 217, which serves as a substrate support, is configured to support, for example, 25 to 200 wafers 200 in a horizontal posture and in multiple stages. In addition, the notation of numerical ranges such as “25 to 200” herein implies that the lower limit value and the upper limit value are included in that range. Thus, for example, “25 to 200” implies “25 or more and 200 or less.” This applies similarly to other numerical ranges. Heat insulation plates 218, which are made of, for example, a heat-resistant material such as quartz or SiC, etc., are supported in multiple stages at a bottom of the boat 217.

A temperature sensor 263 is installed as a temperature detector inside the reaction tube 203. Regulating a power supplied to the heater 207 based on temperature information detected by the temperature sensor 263 may allow an interior of the process chamber 201 or the wafer 200 to achieve a desired temperature distribution. The temperature sensor 263 is provided along the inner wall of the reaction tube 203.

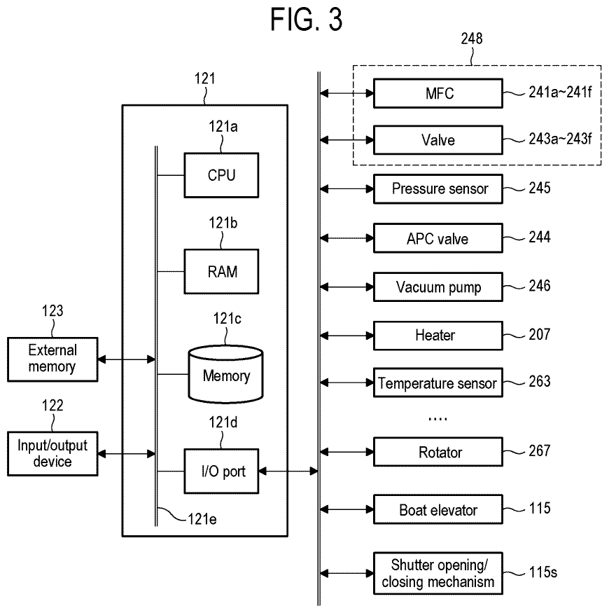

As illustrated in FIG. 3, the controller 121, which is a control part, is configured as a computer including a central processing unit (CPU) 121a, a random access memory (RAM) 121b, a memory 121c, and an I/O port 121d. The RAM 121b, memory 121c, and I/O port 121d are configured to be capable of exchanging data with the CPU 121a through an internal bus 121e. The controller 121 is connected to an input/output device 122, which is formed of, for example, a touch panel and others. Further, the controller 121 is made to enable a connection of an external memory 123 thereto. In addition, the substrate processing apparatus may be configured to include a single controller, or may be configured to include a plurality of controllers. In other words, control for performing a process sequence to be described later may be performed using a single controller, or may be performed using a plurality of controllers. Further, the plurality of controllers may be configured as a control system by being connected to one another through a wired or wireless communication network, and control for performing the process sequence to be described later may be performed by the entire control system. When the term “controller” is used herein, it may include a single controller, may include a plurality of controllers, or may include a control system composed of a plurality of controllers.

The memory 121c is configured by, for example, a flash memory, a hard disk drive (HDD), a solid state drive (SSD), and others. The memory 121c stores, in a readable manner, control programs for controlling the operation of the substrate processing apparatus, process recipes including procedures, conditions, etc., of substrate processing to be described later, and others. The process recipes are combinations that cause the controller 121 to execute each procedure of substrate processing to be described later, in the substrate processing apparatus, to obtain predetermined results and function as programs. Hereinafter, the process recipes and the control programs are collectively referred to simply as “program.” Further, the process recipes are also simply referred to as “recipe.” The term “program” as used herein may refer to a case of solely including the recipe, a case of solely including the control program, or a case of including both. The RAM 121b is configured as a memory area (work area) where programs, data, and others read by the CPU 121a are temporarily held.

The I/O port 121d is connected to the above-described MFCs 241a to 241f, valves 243a to 243f, pressure sensor 245, APC valve 244, vacuum pump 246, temperature sensor 263, heater 207, rotator 267, boat elevator 115, shutter opening/closing mechanism 115s, and others.

The CPU 121a is configured to be capable of reading and executing the control program from the memory 121c as well as to be capable of reading the recipe from the memory 121c in response to an input such as an operation command from the input/output device 122. The CPU 121a is configured to be capable of, according to contents of the recipe thus read, controlling the flow rate regulating operations of various substances (various gases) by the MFCs 241a to 241f, the opening/closing operations of the valves 243a to 243f, the opening/closing operation of the APC valve 244, the pressure regulating operation by the APC valve 244 based on the pressure sensor 245, the startup and shutdown of the vacuum pump 246, the temperature regulating operation of the heater 207 based on the temperature sensor 263, the rotation and rotational speed adjusting operation of the boat 217 by the rotator 267, the raising and lowering operations of the boat 217 by the boat elevator 115, the opening/closing operation of the shutter 219s by the shutter opening/closing mechanism 115s, and others.

The controller 121 may be configured by installing the aforementioned program recorded and stored in the external memory 123 onto the computer. The external memory 123 includes, for example, a magnetic disk such as HDD, an optical disk such as CD, a magneto-optical disk such as MO, a semiconductor memory such as USB memory or SSD, and others. The memory 121c and the external memory 123 are configured as computer-readable recording media. Hereinafter, these are collectively referred to simply as “recording medium.” The term “recording medium” as used herein may refer to a case of solely including the memory 121c, a case of solely including the external memory 123, or a case of including both. In addition, providing the program to the computer may be done using a communication means such as the Internet or a dedicated line without using the external memory 123.

### (2) Substrate Processing Step

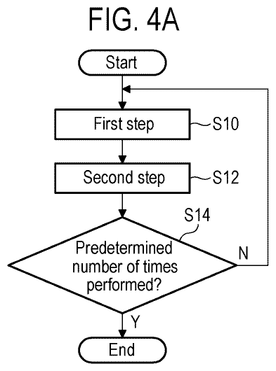

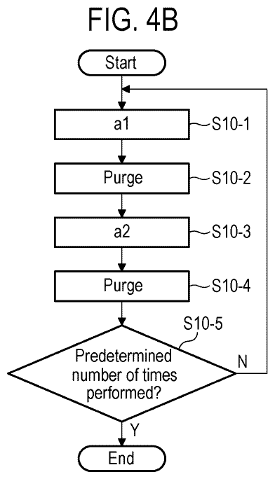

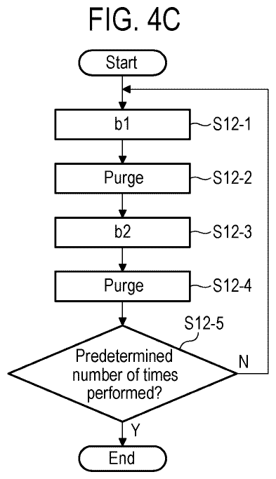

As one step of a manufacturing process of semiconductor devices by using the above-described substrate processing apparatus, a method of processing a substrate, i.e., an example of a process sequence for forming a film on the wafer 200 serving as a substrate with a three-dimensional structure, i.e., recesses such as trenches, grooves, or holes formed on a surface thereof is described mainly with reference to FIGS. 4A to 4C and 5A to 51. In the following description, the operation of each component constituting the substrate processing apparatus is controlled by the controller 121.

In a process sequence of the present embodiments,
(a1) a step of supplying a first modifying gas to the wafer 200 to form the first modified layer 150 on at least a portion of the wafer 200, and (a2) a step of supplying a first removal gas to the wafer 200 to remove a portion of the first modified layer 150 from the wafer 200 are performed a predetermined number of times as a first step, and
(b1) a step of supplying a process gas to the wafer 200 to preferentially process an area where the first modified layer 150 is not formed over an area where the first modified layer 150 is present, and (b2) a step of supplying a reactant gas to the wafer 200, are performed a predetermined number of times as a second step after the first step,
wherein the first step and the second step are performed a predetermined number of times.

In other words, as illustrated in FIG. 4A, the first step is executed in step S10. In the first step, as illustrated in FIG. 4B, procedure a1 is executed in step S10-1, and purge is executed in the process chamber 201 in step S10-2. Procedure a2 is executed in step S10-3, and purge is executed in the process chamber 201 in step S10-4. In step S10-5, it is determined whether steps S10-1 to S10-4 are executed a preset predetermined number of times. If the determination is negative, the process returns to step S10-1. If the determination is affirmative, the first step is terminated and the process proceeds to step S12, where the second step is executed.

In the second step, as illustrated in FIG. 4C, procedure b1 is executed in step S12-1, and purge is executed in the process chamber 201 in step S12-2. Procedure b2 is executed in step S12-3, and purge is executed in the process chamber 201 in step S12-4. In step S12-5, it is determined whether steps S12-1 to S12-4 are executed a preset predetermined number of times. If the determination is negative, the process returns to step S12-1. If the determination is affirmative, the second step is terminated and the process proceeds to step S14.

In step S14, it is determined whether the first and second steps are executed a preset predetermined number of times. If the determination is negative, the process returns to step S10. If the determination is affirmative, the process is terminated.

The term “wafer” as used herein may refer to a wafer itself, or a stacked body including the wafer and a predetermined layer or film formed on a surface of the wafer. The term “surface of the wafer” as used herein may refer to the surface of the wafer itself, or a surface of a predetermined layer formed on the wafer. When it is stated herein “a predetermined layer is formed on the wafer”, it may mean that the predetermined layer is directly formed on the surface of the wafer itself, or that the predetermined layer is formed on a layer or the like formed on the wafer. The term “substrate” as used herein is synonymous with the term “wafer.”

The term “layer” as used herein includes at least one selected from the group of a continuous layer and a discontinuous layer. For example, a deposited layer may include a continuous layer, a discontinuous layer, or both.

When describing herein the adsorption or reaction of each of a first modifying gas, a first removal gas, a second modifying gas, a second removal gas, a process gas, and a reactant gas to the surface of the wafer 200, it may include a mode in which they are adsorbed on or react with the surface of the wafer 200 in an undecomposed state, as well as a mode in which they decompose or their ligands are desorbed to produce intermediates that are adsorbed on or react with the surface of the wafer 200.

### (Wafer Charging and Boat Loading)

A plurality of wafers 200 are charged into the boat 217 (wafer charging). The shutter 219s is moved by the shutter opening/closing mechanism 115s to open the opening at the lower end of the manifold 209 (shutter-open). Thereafter, the boat 217 supporting the plurality of wafers 200 is lifted by the boat elevator 115 and is loaded into the process chamber 201 (boat loading). At this time, the seal cap 219 seals the lower end of the manifold 209 via the O-ring 220b. In this way, as illustrated in FIG. 1, the wafers 200 are prepared (provided) in the process chamber 201.

### (Pressure Regulation and Temperature Regulation)

After the boat loading is completed, the interior of the process chamber 201, i.e., a space where the wafers 200 are present, is vacuum-exhausted (decompression-exhausted) by the vacuum pump 246 to reach a desired pressure (degree of vacuum). At this time, the internal pressure of the process chamber 201 is measured by the pressure sensor 245, and the APC valve 244 is feedback-controlled based on the pressure information measured. Further, the wafers 200 in the process chamber 201 are heated to reach a desired processing temperature by the heater 207. At this time, the power supplied to the heater 207 is feedback-controlled based on the temperature information detected by the temperature sensor 263 so as to achieve a desired temperature distribution in the process chamber 201. Further, the rotation of the wafers 200 is initiated by the rotator 267. The vacuum-exhaust of the process chamber 201 and the heating and rotation of the wafers 200 continue at least until the wafers 200 are completely processed.

### (Film Formation)

Thereafter, the following is executed sequentially.

[a1]

In this procedure, a first modifying gas is supplied to the wafer 200 in the process chamber 201, where in the present embodiments, the wafer 200 includes a recess on a surface thereof, to form the first modified layer 150 on at least a portion of the wafer 200.

Specifically, the valve 243a is opened to flow the first modifying gas into the gas supply pipe 232a. The first modifying gas is regulated in flow rate by the MFC 241a, is supplied into the process chamber 201 through the nozzle 249a, and is exhausted from the exhaust port 231a. At this time, the first modifying gas is supplied to the wafer 200 from a lateral side of the wafer 200 (first modifying gas supply). At this time, the valves 243d to 243f may be opened to supply an inert gas into the process chamber 201 through the respective nozzles 249a to 249c.

Processing conditions when supplying the first modifying gas in this procedure are exemplified as follows:
Processing temperature: 350 to 700 degrees C., particularly 500 to 600 degrees C.;
Processing pressure: 1 to 10,000 Pa, particularly 10 to 1,333 Pa;
First modifying gas supply flow rate: 0.01 to 3 slm, particularly 0.1 to 1 slm;
First modifying gas supply time: 10 to 120 seconds, particularly 20 to 60 seconds; and
Inert gas supply flow rate (per gas supply pipe): 0 to 10 slm.

In addition, the processing temperature herein refers to a temperature of the wafer 200 or an internal temperature of the process chamber 201, and the processing pressure herein refers to the internal pressure of the process chamber 201. Further, the processing time refers to the time during which the processing is continued. Further, the supply flow rate refers to the flow rate of a gas supplied into the process chamber 201. Further, if the supply flow rate includes 0 slm, “0 slm” refers to a case where no substance (gas) is supplied into the process chamber 201. These apply similarly to the following description.

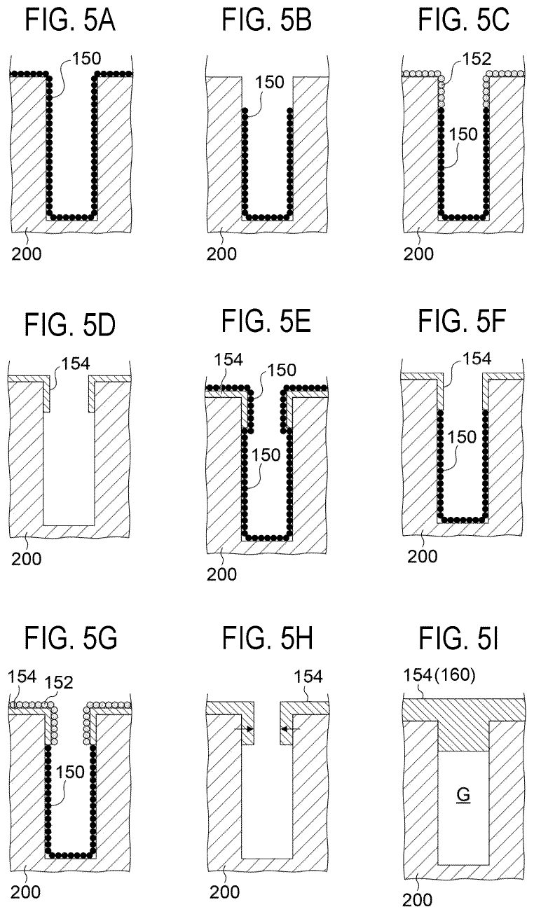

By supplying the first modifying gas to the wafer 200 under the above-described processing conditions, the first modifying gas may be adsorbed on adsorption sites present on the surface of the wafer 200 (see FIG. 5A). Specifically, this allows the first modifying gas to be adsorbed discontinuously on at least a portion of an upper surface and inner surface of the recess (sidewall surface and bottom surface inside the recess)(see FIG. 5A). More specifically, this allows the first modifying gas to be adsorbed discontinuously over the entire surface from an opening side to a depth side of the recess. Hereinafter, the “opening side of the recess” is referred to as the “opening side,” and the “depth side of the recess” is referred to as the “depth side.” In addition, as used herein, the “depth side of the recess” refers to, for example, a location and its surrounding area, such as a bottom of the recess, where the gas supplied to the wafer 200 is difficult to reach, compared to the opening side.

As for the first modifying gas, a halogen-containing gas that contains at least one selected from the group of Cl, F, Br, and I may be used. The halogen-containing gas contains at least one selected from the group of halogen groups such as Cl, F, Br, and I groups as functional groups. For example, halogen elemental gases such as fluorine (F₂) gas, chlorine (Cl₂) gas, bromine (Br₂) gas, and iodine (I₂) gas, interhalogen compound gases such as chlorine fluoride (ClF₃) gas, bromine chloride (BrCl) gas, iodine chloride (ICl) gas, iodine pentafluoride (IF₅) gas, bromine trifluoride (BrF₃) gas, and iodine bromide (IBr) gas, hydrogen halide compound gases such as hydrogen chloride (HCl) gas, hydrogen fluoride (HF) gas, hydrogen bromide (HBr) gas, and hydrogen iodide (HI) gas, or a combination of these gases may be used as the first modifying gas.

Further, gases containing organic compounds may be used as the first modifying gas. The gases containing organic compounds may include gases containing at least one selected from the group of ether compounds, ketone compounds, amine compounds, organic hydrazine compounds, and compounds with a cyclic structure in the molecular structure. The gases containing ether compounds may include gases containing at least one selected from the group of dimethyl ether, diethyl ether, methyl ethyl ether, propyl ether, isopropyl ether, furan, tetrahydrofuran, pyran, tetrahydropyran, and others. The gases containing ketone compounds may include gases containing at least one selected from the group of dimethyl ketone, diethyl ketone, methyl ethyl ketone, methyl propyl ketone, and others. The gases containing amine compounds may include gases containing at least one selected from the group of methylamine compounds such as monomethylamine, dimethylamine and trimethylamine, ethylamine compounds such as monoethylamine, diethylamine, and triethylamine, and methylethylamine compounds such as dimethylethylamine and methyldiethylamine. The gases containing organic hydrazine compounds may include gases containing at least one selected from the group of methylhydrazine-based gases such as monomethylhydrazine, dimethylhydrazine, and trimethylhydrazine. The gases containing compounds with a cyclic structure may include gases with a cyclic structure containing at least one selected from the group of a cycloalkyl group, a benzene ring structure, and carbon in the molecular structure such as methoxycyclopentane, anisole, and trimethylene oxide. One or more of these gases may be used as the first modifying gas.

Alkyl group-containing gases that contain alkyl groups may also be used. A methane (CH₄) gas, ethane (C₂H₆) gas, propane (C₃H₈) gas, and others may also be used as the first modifying gas.

As for the inert gas, for example, nitrogen (N₂) gas or noble gases such as argon (Ar) gas, helium (He) gas, neon (Ne) gas, and xenon (Xe) gas may be used. One or more of these gases may be used as the inert gas. This applies similarly to each step to be described later.

After the first modifying gas is adsorbed on the surface of the wafer 200 (the upper surface and inner surface of the recess), the valve 243a is closed to stop the supply of the first modifying gas into the process chamber 201. Then, the interior of the process chamber 201 is vacuum-exhausted, removing any residual gaseous substance and others from the process chamber 201. At this time, the valves 243d to 243f are opened to supply the inert gas into the process chamber 201 through the nozzles 249a to 249c. The inert gas supplied from the nozzles 249a to 249c acts as a purge gas, thereby purging the space where the wafer 200 is present, i.e. the interior of the process chamber 201 (purge).

[a2]

After terminating procedure a1, a first removal gas is supplied to the wafer 200 in the process chamber 201.

Specifically, the valve 243c is opened to flow the first removal gas into the gas supply pipe 232c. The first removal gas is regulated in flow rate by the MFC 241c, is supplied into the process chamber 201 through the nozzle 249c, and is exhausted from the exhaust port 231a. At this time, the first removal gas is supplied to the wafer 200 (first removal gas supply). At this time, the valves 243d to 243f may be opened to supply an inert gas into the process chamber 201 through the respective nozzles 249a to 249c.

Processing conditions when supplying the first removal gas in this procedure are exemplified as follows:
Processing temperature: 400 to 900 degrees C., particularly 500 to 800 degrees C.;
Processing pressure: 1 to 2,666 Pa, particularly 10 to 1,333 Pa;
First removal gas supply flow rate: 0.001 to 2 slm, particularly 0.01 to 1 slm;
First removal gas supply time: 1 to 40 seconds, particularly 2 to 20 seconds; and
Inert gas supply flow rate (per gas supply pipe): 0 to 10 slm. The other processing conditions may be similar to those when supplying the first modifying gas in procedure a1.

By supplying the first removal gas to the wafer 200 under the above-described processing conditions, a portion of the first modified layer 150 may be removed from the surface of the wafer 200. For example, as illustrated in FIG. 5B, a portion of the first modified layer 150 on the upper surface of the recess and on the opening side of the recess may be removed.

As for the first removal gas, for example, gases including a reducing gas, an oxidizing gas, a nitriding gas, a sulfurizing gas, a selenizing gas, a tellurizing gas, and others may be used. One or more of these gases may be used as the first removal gas.

Examples of the reducing gas may include a hydrogen (H₂) gas, deuterium (D₂) gas, borane (BH₃) gas, diborane (B₂H₆) gas, carbon monoxide (CO) gas, ammonia (NH₃) gas, monosilane (SiH₄) gas, disilane (Si₂H₆) gas, trisilane (Si₃H₅) gas, monogerman (GeH₄) gas, digerman (Ge₂H₆), and others, and one or more of these gas may be used. Further, for example, an oxidizing gas containing oxygen (O) may be used as the first removal gas. Examples of the oxidizing gas may include oxygen (O₂), ozone (O₃), water vapor (H₂O), a mixed gas of H₂ and O₂, hydrogen peroxide (H₂O₂), nitrous oxide (N₂O), and others, and one or more of these gases may be used. Examples of the nitriding gas may include hydrogen nitride-based gases such as ammonia (NH₃) gas, diazene (N₂H₂) gas, hydrazine (N₂H₄) gas, and N₃H₈ gas, and one or more of these gases may be used. Examples of the sulfurizing gas may include gases containing sulfane (H₂S), disulfane (H₂S₂), diammonium sulfide ((NH₄)₂S), dimethyl sulfide ((CH₃)₂S), and other, and one or more of these gases may be used. Examples of the selenizing gas may include gases containing selane (H₂Se), diselane (H₂Se₂), dimethylselenium ((CH₃)₂Se), and others, and one or more of these gases may be used. Examples of the tellurizing gas may include gases containing tellane (H₂Te), ditellane (H₂Te₂), dimethyltellurium ((CH₃)₂Te), and others, and one or more of these gases may be used.

After removing a portion of the first modified layer 150 on the surface of the wafer 200 (the upper surface and inner surface of the recess), the valve 243c is closed to stop the supply of the first removal gas into the process chamber 201. Then, the process chamber 201 is purged in the same procedure as the purge performed after terminating procedure a1.

[Performing Predetermined Number of Times—a]

By performing the first step, which includes performing procedure a1, purge, procedure a2, and purge in this order, a predetermined number of times (n1 times, where n1 is an integer of 1, or 2 or more), it is possible to form the first modified layer 150, a portion of which is removed, on the surface of the wafer 200 (the inner surface of the recess). In addition, the purge may be omitted in the first step. Further, procedures a1 and a2 may be performed at least partially simultaneously.

[b1]

Next, a process gas is supplied to the wafer 200 in the process chamber 201. In other words, the process gas is supplied to the wafer 200 after the first modified layer 150 is formed on the upper surface and inner surface of the recess and a portion of the first modified layer 150 is removed.

Specifically, the valve 243b is opened to flow the process gas into the gas supply pipe 232b. The process gas is regulated in flow rate by the MFC 241b, is supplied into the process chamber 201 through the nozzle 249b, and is exhausted from the exhaust port 231a. At this time, the process gas is supplied to the wafer 200 (process gas supply). At this time, the valves 243d to 243f may be opened to supply an inert gas into the process chamber 201 through the respective nozzles 249a to 249c.

Processing conditions when supplying the process gas in this procedure are exemplified as follows:
Processing temperature: 400 to 900 degrees C., particularly 500 to 800 degrees C.;
Processing pressure: 1 to 5,000 Pa, particularly 10 to 1,333 Pa;
Process gas supply flow rate: 0.01 to 2 slm, particularly 0.1 to 1 slm;
Process gas supply time: 5 to 50 seconds, particularly 6 to 30 seconds; and
Inert gas supply flow rate (per gas supply pipe): 0 to 10 slm. The other processing conditions may be similar to those when supplying the first modifying gas in procedure a1.

By supplying the process gas to the wafer 200 under the above-described processing conditions, the process gas may be adsorbed on a location on the surface of the wafer 200 where a portion of the first modified layer 150 is removed, thereby forming the process layer 152 (see FIG. 5C).

As for the process gas, for example, a silane-based gas containing silicon (Si) may be used. Examples of the silane-based gas may include gases containing Si and halogens, i.e., halosilane-based gases. The halogens includes chlorine (Cl), fluorine (F), bromine (Br), iodine (I), and others. In other words, the halosilane-based gases contain, as functional groups, at least one selected from the group of halogen groups such as chloro (Cl), fluoro (F), bromo (Br), and iodine (I) groups.

Examples of the process gas may include chlorosilane-based gases such as monochlorosilane (SiH₃Cl) gas, dichlorosilane (SiH₂Cl₂) gas, trichlorosilane (SiHCl₃) gas, tetrachlorosilane (SiCl₄) gas, hexachlorodisilane (Si₂Cl₆) gas, and octachlorothrisilane (Si₃Cl₈) gas, and one or more of these gases may be used.

In addition to the chlorosilane-based gases, other examples of the process gas may include fluorosilane-based gases such as tetrafluorosilane (SiF₄) gas, trifluorosilane (SiHF₃) gas, and difluorosilane (SiH₂F₂) gas, bromosilane-based gases such as tetrabromosilane (SiBr₄) gas, tribromosilane (SiHBr₃) gas, and dibromosilane (SiH₂Br₂) gas, and iodosilane-based gases such as tetraiodosilane (SiI₄) gas, triiodosilane (SiHI₃) gas, and diiodosilane (SiH₂I₂) gas, and one or more of these gases may be used.

Further, for example, gases containing Si as a first element and organics ligand may be used as the process gas. Examples of the gases containing Si and organic ligands may include aminosilane-based gases such as tetrakis(dimethylamino)silane (Si[N(CH₃)₂]₄) gas, tris(dimethylamino)silane (Si[N(CH₃)₂]₃H) gas, bis(diethylamino)silane (Si[N(C₂H₅)₂]₂H₂) gas, bis(tert-butylamino)silane (SiH₂[NH(C₄H₉)]₂) gas, and (diisopropylamino)silane (SiH₃[N(C₃H₇)₂]) gas. Further, for example, gases containing Si as the first element and hydrogen (H) groups may be used as the process gas. Examples of the gases containing Si and H groups may include monosilane (SiH₄) and disilane (Si₂H₆), and one or more of these gases may be used as the process gas.

In addition to these, for example, gases containing Si and alkyl groups as the organic ligands, i.e., alkylsilane-based gases, may also be used as the process gas. The alkyl groups may be either linear or branched. Examples of the alkyl groups may include methyl, ethyl, n-propyl, n-butyl, isopropyl, isobutyl, sec-butyl, tert-butyl groups, and others.

Further, for example, one or more of tungsten (W), titanium (Ti), molybdenum (Mo), tantalum (Ta), cobalt (Co), yttrium (Y), ruthenium (Ru), hafnium (Hf), zirconium (Zr), aluminum (Al), boron (B), gallium (Ga), indium (In), phosphorus (P), and carbon (C) may be used.

For example, gases containing the first element and halogen elements may be used as the process gas. Examples of these gases may include hexachlorotungsten (WCl₆), hexafluorotungsten (WF₆), titanium tetrachloride (TiCl₄), titanium tetrafluoride (TiF₄), molybdenum pentachloride (MoCl₅), molybdenum pentafluoride (MoF₅), molybdenum dioxide dichloride (MoO₂Cl₂), molybdenum oxytetrachloride (MoOCl₄), tantalum pentachloride (TaCl₅), tantalum pentafluoride (TaF₅), cobalt difluoride (CoF₂), cobalt dichloride (CoCl₂), yttrium trifluoride (YF₃), yttrium trichloride (YCl₃), ruthenium trichloride (RuCl₃), ruthenium trifluoride (RuF₃), hafnium tetrachloride (HfCl₄), hafnium tetrafluoride (HfF₄), zirconium tetrachloride (ZrCl₄), zirconium tetrafluoride (ZrF₄), aluminum trichloride (AlCl₃), aluminum trifluoride (AlF₃), and others. Further, for example, boron trifluoride (BF₃), boron trichloride (BCl₃), gallium trifluoride (GaF₃), gallium trichloride (GaCl₃), indium trifluoride (InF₃), indium trichloride (InCl₃), phosphorus trifluoride (PF₃), phosphorus pentafluoride (PF₅), phosphorus trichloride (PCl₃), phosphorus pentachloride (PCl₅), carbon tetrafluoride (CF₄), carbon tetrachloride (CCl₄), trifluoromethane (CHF₃), fluoromethane (CH₃F), trichloromethane (CHCl₃), chloromethane (CH₃Cl), and others may be used as the process gas. For example, gases containing the first element and Br groups, or gases containing the first element and I groups may be used as the process gas.

In addition to these, for example, gases containing the first element and organic ligands, or gases containing the first element and hydrogen groups may be used as the process gas. Examples of the organic ligands may include alkyl, cycloalkyl, alkoxide, phenyl, and cyclopentadienyl groups. For example, hexadimethylaminoditungsten (W₂[N(CH₃)₂]₆), bisterbutylimido bisdimethylamido tungsten ((t-C₄H₉NH)₂W=(Nt-C₄H₉)₂), tetrakisethylmethylaminotitanium (Ti[N(C₂H₅)(CH₃)]₄), bisethylcyclopentadienylruthenium (Ru(CH₂CH₃)Cp)₂), biscyclopentadienylruthenium (Ru(Cp)₂), tetrakisethylmethylaminohafnium (Hf[N(CH₃)(CH₂CH₃)]₄), tetrakisdiethylaminohafnium (Hf[N(CH₂CH₃)₂]₄), tetrakisdimethylaminohafnium (Hf[N(CH₃)₂]₄), trisdimethylaminocyclopentadienylhafnium ((Cp)Hf[N(CH₃)₂]₃), tetrakisethylmethylaminozirconium (Zr[N(CH₃)(CH₂CH₃)]₄), tetrakisdiethylaminozirconium (Zr[N(CH₂CH₃)₂]₄), tetrakisdimethylaminozirconium (Zr[N(CH₃)₂]₄), trisdimethylaminocyclopentadienylzirconium ((Cp)Zr[N(CH₃)₂]₃), trimethylaluminum (Al(CH₃)₃), boron (BH₃), trimethyl gallium (Ga(CH₃)₃), trimethylindium (In(CH₃)₃), phosphine (PH₃), methane (CH₄), and others may be used as the process gas.

Herein, the first modifying gas is a gas that inhibits the process gas from being adsorbed on the wafer 200. Specifically, the functional groups, which are contained in the first modifying gas and are formed (exposed) on the upper surface and inner surface of the recess, inhibit the adsorption of the process gas on the wafer 200 (the upper surface and inner surface of the recess). Thus, the process gas is not adsorbed on the first modified layer 150 on the surface of the wafer 200, but instead is adsorbed on areas where a portion of the first modified layer 150 is removed. For example, in the present embodiments, as illustrated in FIG. 5C, the process gas is adsorbed on the upper surface of the recess and the opening side of the recess on the wafer 200. Further, in general, a gas supplied to the wafer 200 tends to easily reach the upper surface of the recess and the opening side of the recess on the wafer 200, but is less likely to reach the depth side of the recess. Therefore, a position of the process gas adsorbed on the wafer 200 may be controlled by regulating the processing conditions of procedures a1 and a2 and controlling distribution of the first modified layer 150 formed on the wafer 200 or distribution of the first modified layer 150 removed from the wafer 200.

Herein, when it is stated herein “the process gas is not adsorbed on the first modified layer 150,” it means cases where none the process gas is adsorbed on the first modified layer, as well as cases where an extremely small amount of the process gas is adsorbed on the first modified layer. For example, this includes cases where the process gas is adsorbed on approximately 1% of the first modified layer on the wafer 200, and particularly, cases where the process gas is adsorbed on 1% or less of the first modified layer.

By performing procedures a1, a2, and b1, a layer in which both the first modifying gas and the process gas are adsorbed may be formed on adsorption sites provided on the surface of the wafer 200.

After procedure b1, the valve 243b is closed to stop the supply of the process gas into the process chamber 201. Then, the process chamber 201 is purged in the same procedure as the purge performed after terminating procedure a1.

[b2]

After procedure b1 is terminated, a reactant gas is supplied to the wafer 200.

Specifically, the valve 243c is opened to flow the reactant gas into the gas supply pipe 232c. The reactant gas is regulated in flow rate by the MFC 241c, is supplied into the process chamber 201 through the nozzle 249c, and is exhausted from the exhaust port 231a. At this time, the reactant gas is supplied to the wafer 200 (reactant gas supply). At this time, the valves 243d to 243f may be opened to supply an inert gas into the process chamber 201 through the respective nozzles 249a to 249c.

Processing condition when supplying the reactant gas in this procedure are exemplified as follows:
Processing pressure: 1 to 4,000 Pa, particularly 1 to 1,000 Pa;
Reactant gas supply flow rate: 0.1 to 10 slm, particularly 1 to 5 slm; and
Reactant gas supply time: 1 to 120 seconds, particularly 10 to 60 seconds. The other processing conditions may be similar to those when supplying the first modifying gas in procedure a1.

By supplying the reactant gas to the wafer 200 under the above-described processing conditions, at least a portion of the process layer 152 formed on the inner surface of the recess reacts with the reactant gas, allowing formation of the first layer 154 (see FIG. 5D).

As for the reactant gas, for example, gases including the above-described reducing gas, oxidizing gas, nitriding gas, sulfurizing gas, selenizing gas, tellurizing gas, and others may be used. One or more of these gases may be used as the reactant gas. Herein, the first removal gas and the reactant gas may be gases with the same molecular structure. Further, the first removal gas and the reactant gas may be gases with different molecular structures. Further, in procedure b2, removal of at least a portion of the first modified layer 150 on the wafer 200 by the reactant gas may occur in parallel with the formation of the first layer 154.

After procedure b2, the valve 243c is closed to stop the supply of the reactant agent into the process chamber 201. Then, the process chamber 201 is purged in the same procedure as the purge performed after terminating procedure a1.

[Performing Predetermined Number of Times—b]

By performing the second step, which includes performing procedure b1, purge, procedure b2, and purge in this order, a predetermined number of times (n2 times, where n2 is an integer of 1, or 2 or more), it is possible to form the first layer 154 with a predetermined thickness on the surface of the wafer 200 (the inner surface of the recess). In addition, the purge may be omitted in the second step. Further, procedures b1 and b2 may be performed partially simultaneously, allowing the process gas and the reactant gas to react in a gas phase. Further, procedure b2 may be omitted and procedure b1 may be performed two times. In this case, it is possible to form the process layer 152 with a predetermined thickness on the surface of the wafer 200 (the inner surface of the recess).

### [Performing Predetermined Number of Times]

By performing a first cycle, in which the above-described first and second steps are performed in this order, a predetermined number of times (n times, where n is an integer of 1, or 2 or more), it is possible to form a film 160 with a desired composition on an upper surface of the wafer 200 and the opening side of the recess. For example, in the second time of performing a1 of the first cycle, as illustrated in FIG. 5E, the first modified layer 150 is formed on the upper surface of the wafer 200 and the opening side of the recess, including a surface of the first layer 154. In procedure a2, as illustrated in FIG. 5F, a portion of the first modified layer 150 on the upper surface of the wafer 200 and the opening side of the recess is removed. In procedure b1, as illustrated in FIG. 5G, the process layer 152 is formed on the upper surface of the wafer 200 and the opening side of the recess. In procedure b2, as illustrated in FIG. 5H, the first layer 154 with a greater thickness is formed on the upper surface of the wafer 200 and the opening side of the recess. By further repeating the first cycle, the opening gradually narrows, and it is possible to form an air gap G as illustrated in FIG. 5I.

### (After-Purge and Atmospheric Pressure Recovery)

After the film formation is completed, an inert gas serving as a purge gas is supplied into the process chamber 201 from the respective nozzles 249a to 249c, and is exhausted from the exhaust port 231a. Thus, the interior of the process chamber 201 is purged, and any gases and reaction by-products remaining in the process chamber 201 are removed from the interior of the process chamber 201 (after-purge). Thereafter, the atmosphere within the process chamber 201 is replaced with the inert gas (inert gas replacement), and the internal pressure of the process chamber 201 is restored to normal pressure (atmospheric pressure recovery).

### (Boat Unloading and Wafer Discharge)

Thereafter, the seal cap 219 is lowered by the boat elevator 115 to open the lower end of the manifold 209. Then, the boat 217 is unloaded out of the reaction tube 203 (boat unloading). After the boat unloading, the shutter 219s is moved, and the opening at the lower end of the manifold 209 is sealed by the shutter 219s and the O-ring 220c (shutter-close). After that, the processed wafer 200 is taken out from the boat 217 (wafer discharge).

### (3) Effects of Present Embodiments

According to the present embodiments, one or more of the following effects are obtained, in addition to the above-described effects.
(a) By performing procedure a2 after procedure a1, distribution of the first modified layer 150 in the recess of the wafer 200 may be controlled. This allows control over locations where processing is likely to progress in the second step. For example, the following types of distribution of the first modified layer may be formed.
(1) A density of the first modified layer formed at a center of the recess is higher than that at the opening and depth of the recess.
(2) A density of the first modified layer formed at the depth of the recess is higher than that at the opening of the recess.
(3) A density of the first modified layer is approximately uniform from the opening to the depth of the recess.
(b) The first removal gas and the reactant gas may possess the same molecular structure. In this case, the reactant gas supply system and the first removal gas supply system may be unified. Therefore, apparatus configuration may be simplified.
(c) The first removal gas and the reactant gas may possess different molecular structures. In this case, gases with different reactivities may be used in procedures a2 and b2. For example, when forming an oxide film as the film 160, O₂ may be used as the first removal gas, while O₃ with higher reactivity than O₂ may be used as the reactant gas. Further, when forming an oxynitride film as the film 160, NH₃ may be used as the first removal gas, while O₃ with higher reactivity than N₂O may be used as the reactant gas. In other words, a gas with lower reactivity than the reactant gas may be used as the first removal gas. In such cases, excessive oxidation (modification) of the process layer 152 or the first layer 154 already formed on the wafer 200, or an underlying layer may be prevented.

On the other hand, for example, when forming an oxide film as the film 160, O₃ may be used as the first removal gas, while O₂ may be used as the reactant gas. Further, when forming an oxynitride film as the film 160, O₃ may be used as the first removal gas, while NH₃ may be used as the reactant gas. In other words, a gas with higher reactivity than the reactant gas may be used as the first removal gas. Thus, even in procedure a1, oxidation (modification) of the process layer 152 or the first layer 154 already formed on the wafer 200, or an underlying film of the process layer 152 or the first layer 154 may be progressed.
(d) It is desirable to make an exposure amount of the reactant gas to the wafer 200 in procedure b2 greater than an exposure amount of the first modifying gas to the wafer 200 in procedure a1. This enhances the likelihood of the reactant gas reaching the depth side of the recess. Further, if the first removal gas and the reactant gas possess the same molecular structure, the reaction between the first removal gas (or the reactant gas) and the first modifying gas becomes easier to occur. Thus, the reaction may progress sufficiently even in the depth side of the recess, enabling uniform processing over the entire recess.

In addition, by satisfying at least one selected from the group of 1 to 6 listed below, the exposure amount of the reactant gas to the wafer 200 in procedure b2 may be increased compared to the exposure amount of the first modifying gas to the wafer 200 in procedure a1.
1. The reactant gas supply time in procedure b2 is made longer than the first modifying gas supply time in procedure a1.
2. The processing pressure in procedure b2 is made higher than the processing pressure in procedure a1.
3. The reactant gas supply flow rate in procedure b2 is made higher than the first modifying gas supply flow rate in procedure a1.
4. The inert gas supply flow rate in procedure b2 is made lower than the inert gas supply flow rate in procedure a1.
5. A partial pressure of the reactant gas in the process chamber 201 in procedure b2 is made higher than a partial pressure of the first modifying gas in the process chamber 201 in procedure a1.
6. A molar fraction of the reactant gas in the gases inside the process chamber 201 in procedure b2 is made higher than a molar fraction of the first modifying gas in procedure a1.
(e) It is desirable to make the upper surface and inner surface of the recess where the first modifying gas is adsorbed be in a state where first functional groups derived from the first modifying gas are exposed. In procedure a2, it is desirable to replace at least a portion of first functional groups, which form at least a portion of the first modified layer, with second functional groups that exhibit higher reactivity to the process gas than the first functional groups. In such cases, the first modified layer may be removed in a short time. Therefore, this helps to prevent a reduction in the number of substrates that may be processed per unit time (throughput).
(f) It is desirable that either (1) or (2) below is satisfied.
(1) The first modifying gas and the process gas contain halogen elements.
(2) The first modifying gas and the process gas are organic compounds or contain organic ligands.

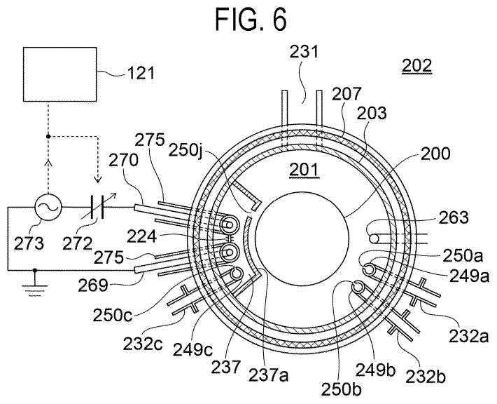

In such cases, the inhibition of process gas adsorption on the wafer 200 by the first modifying layer becomes easier to occur. This enables even more precise control over locations where processing is likely to progress in the second step.
(g) If a film is formed on the wafer 200 in the second step, it is desirable that the first modifying gas does not contain main constituent element of the film. This ensures that the film is likely to be preferentially formed on areas where the first modified layer is not formed over areas where the first modified layer is formed.
(h) The first removal gas may include a gas activated by plasma. A configuration example of the process furnace 202 in such cases is described with reference to FIG. 6. In addition, the same reference numerals are given to elements that are substantially the same as those described in FIG. 1 and descriptions thereof are omitted. FIG. 6 is an example of a cross-sectional view of the process furnace 202 taken along line A-A in FIG. 1. A buffer chamber 237 partitioned by a partition wall 237a is provided inside the reaction tube 203, and the nozzle 249c is disposed in the buffer chamber 237. In the buffer chamber 237, two rod-shaped electrodes 269 and 270, which are made of a conductor, are each introduced into the buffer chamber 237 from a lower portion of the inner wall of the reaction tube 203 to extend upward toward an upper portion of the reaction tube 203 (toward a front of the paper). The rod-shaped electrodes 269 and 270 are installed parallel to the nozzle 249c, respectively. The rod-shaped electrodes 269 and 270 are covered by electrode protective tubes 275 from their top to their bottom. One of the rod-shaped electrodes 269 and 270 is connected to a radio frequency power supply 273 through a matcher 272, while the other is grounded with a reference potential. By applying radio frequency (RF) power between the rod-shaped electrodes 269 and 270 from the radio frequency power supply 273, the first removal gas may be activated by plasma in a plasma generation area 224 between the rod-shaped electrodes 269 and 270. The rod-shaped electrodes 269 and 270, along with the electrode protective tubes 275, primarily constitute an exciter (activator) that excites (activates) gases into a plasma state.

If the first removal gas is activated by plasma, the reactivity of the first removal gas may be increased and subsequently reduced (deactivated) over time. This may enhance a difference in the ease of removal of the first modified layer between locations where the first removal gas easily reaches and locations where the first removal gas is less accessible. This, for example, makes it easier to remove the first modified layer near the opening of the recess while making it more difficult to remove the first modified layer at the center or depth side of the recess. Accordingly, locations where processing is likely to progress in the second step may be more precisely controlled.
(i) The number of repetitions N of the first and second steps may be two or more. By repeating the steps two or more times, the processing at a target position may be facilitated.

### <Modifications>

The process sequence in the present embodiments may be changed as in the following modifications. These modifications may be combined arbitrarily. Unless otherwise specified, processing procedures and processing conditions for each procedure in each modification may be the same as the processing procedures and processing conditions for each procedure in the above-described process sequence.

### (Modification 1)

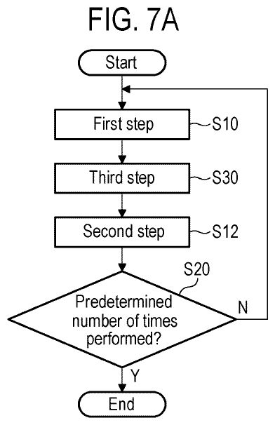

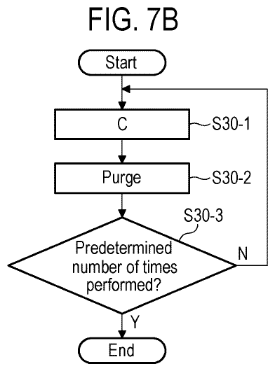

As illustrated in the process sequence of FIG. 7A, after executing the first step and before executing the second step, a third step S30 is executed. In the third step, as illustrated in FIG. 7B, procedure c is performed in step S30-1. Procedure c is to supply a second modifying gas to form a second modified layer 158 on at least a portion of the area of the wafer 200 where the first modified layer 150 is not formed. In step S30-2, purge is performed inside the process chamber 201. In step S30-3, it is determined whether procedure c is executed a preset predetermined number of times. If the determination is negative, the process returns to step S30-1. If the determination is affirmative, the third step is terminated and the process proceeds to step S12, where the second step is executed.

### (A) Effects of Modification 1

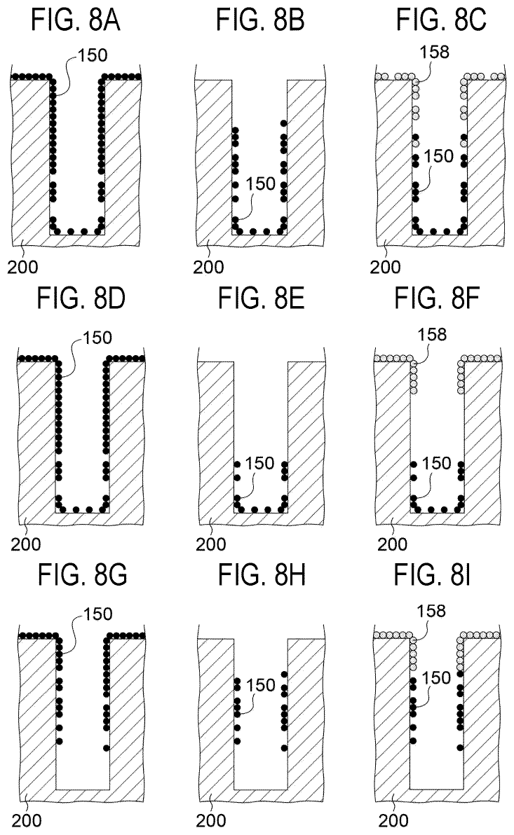

Even in this modification, at least some of the effects of the above-described embodiments may be obtained. Further, the present modification obtains one or more of the following effects.
(a) By executing the third step in this manner, distribution of the modified layers (either or both of the first modified layer and the second modified layer) within the pattern may be more precisely controlled. Specifically, for example, the following types of distribution of the modified layer may be formed.
(1) Densities of the first modified layer 150 and the second modified layer 158 may be made approximately uniform from the opening side to the depth side of the recess. In this case, in the first step, the first modified layer 150 is formed to the depth side of the recess (FIG. 8A), while at least a portion of the first modified layer 150 on the opening side is removed (FIG. 8B). In the third step, the second modified layer 158 is formed in areas where at least a portion of the first modified layer 150 on the opening side is removed (FIG. 8C).
(2) The densities of the first and second modified layers formed at the opening side and the depth side of the recess may be made higher than that at the center of the recess. In this case, in the first step, the first modified layer 150 is formed to the depth of the recess (FIG. 8D), while at least a portion of the first modified layer 150 is removed to a position deeper than a middle of the recess (FIG. 8E). In the third step, the second modified layer 158 is formed on the opening side (FIG. 8F).
(3) If molecular structures of the first modifying gas and the second modifying gas are different, modified layers with different adsorption inhibition effects for the process gas may be formed at the depth side of the recess, near the center of the recess, and at the opening side of the recess. For example, a second modified layer for the process gas may be formed at the opening side, a first modified layer with a smaller adsorption inhibition effect than the second modified layer may be formed near the center, and the first and the second modified layers may be made difficult to be formed at the depth side. In this case, in the first step, the first modified layer 150 is formed deeper than the middle of the recess (to an extent that it is not formed at the bottom) (FIG. 8G), while at least a portion of the first modified layer 150 at the opening side is removed (FIG. 8H). In the third step, the second modified layer 158 is formed on areas where at least a portion of the first modified layer 150 on the opening side is removed (FIG. 8I). This allows the process to increase the ease of progress toward the depth side of the recess where gas penetration is more challenging. Consequently, the process may progress uniformly within the recess, making it easier to form a film of uniform thickness. For example, a case where the first and second modified layers are formed respectively as layers containing X1- and X2-groups, which are functional groups of different halogen elements X1 and X2 is conceivable. In this case, by setting the atomic number of X2 smaller than that of X1 (e.g., using Cl for X1 and F for X2, respectively), an adsorption inhibition effect of the second modified layer may be made greater than that of the first modified layer.
(b) It is desirable to make an exposure amount of the second modifying gas to the wafer 200 in procedure c smaller than an exposure amount of the first modifying gas to the wafer 200 in procedure a1. In this case, since the second modifying gas is supplied to the opening side of the recess after the first modified layer is removed in procedure a2, the formation of the second modified layer is less likely to be inhibited by the first modified layer. Consequently, the above-described effect (control of the distribution of the modified layer) is easier to achieve.
(c) If the first modifying gas and the second modifying gas possess the same molecular structure, the first modifying gas supply system and a second modifying gas supply system may be unified. Therefore, the apparatus configuration may be simplified.
(d) In procedure a2, it is desirable to replace at least a portion of first functional groups on the wafer 200, which constitute at least a portion of the first modified layer, with second functional groups exhibiting higher reactivity to the process gas than the first functional groups. In procedure c, it is desirable to replace at least a portion of the second functional groups with third functional groups, which constitute at least a portion of the second modified layer and possess lower reactivity to the process gas than the second functional groups. In such cases, removal of the first modified layer and formation of the second modified layer may be performed in a short time. Therefore, this helps to prevent a reduction in the number of substrates that may be processed per unit time (throughput).
(e) It is desirable that either (1) or (2) below is satisfied.
(1) The first modifying gas, the process gas, and the second modifying gas contain halogen elements.
(2) The first modifying gas, the process gas, and the second modifying gas are organic compounds or contain organic ligands.

In such cases, the inhibition of process gas adsorption on the wafer 200 by the first modified layer and the second modified layer is likely to occur. This enables even more precise control over locations where processing is likely to progress in the second step.
(f) If a film is formed on the wafer 200 in the second step, it is desirable that the first modifying gas and the second modifying gas do not contain main constituent elements of the film. Thus, it is easier to preferentially form a film on areas where at least one selected from the group of the first modified layer and the second modified layer is not formed over areas where at least one selected from the group of the first modified layer and second modified layer is formed.
(g) The first removal gas may include a gas activated by plasma. If the first removal gas is activated by plasma, the reactivity of the first removal gas may be increased and subsequently reduced (deactivated) over time. This may enhance the difference in the ease of removal of the first modified layer between the locations where the first removal gas easily reaches and the locations where the first removal gas is less accessible. For example, this makes it easier to remove the first modified layer near the opening of the recess while making it more difficult to remove the first modified layer at the center or depth side of the recess. This enables even more precise control over locations where processing is likely to progress in the second step.

### (Modification 2)

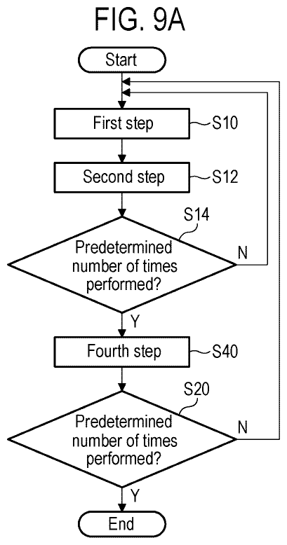

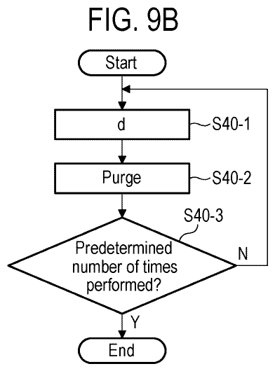

As illustrated in the process sequence of FIG. 9A, after executing the first and second steps a predetermined number of times, a fourth step S40 is executed. In the fourth step, as illustrated in FIG. 9B, procedure d is executed in step S40-1. Procedure d is to supply a second removal gas to remove a portion of the first modified layer 150 from the wafer 200. In step S40-2, purge is performed inside the process chamber 201. In step S40-3, it is determined whether procedure d is executed a preset predetermined number of times. If the determination is negative, the process returns to step S40-1. If the determination is affirmative, the fourth step is terminated.

### (A) Effects of Modification 2

Even in this modification, at least some of the effects of the above-described embodiments and modification may be obtained. Further, the present modification obtains one or more of the following effects.
(a) If the first modified layer 150 remains on the substrate after the second step, that location becomes less responsive to the processing by the second step, compared to other locations. This may cause a reduction in uniformity of processing in an area of the wafer 200 where processing is intended to progress. For example, when forming a film in procedure b, uniformity of the film formed may decrease due to occurrence of insufficient film formation locations (such as pinholes) or an increase in surface roughness of the film. In the fourth step, at least a portion of the first modified layer remaining on the wafer 200 after the second step may be removed by supplying the second removal gas. Therefore, this may improve the uniformity of the film (the uniformity of processing) in the area of the wafer 200 where processing is intended to progress.
(b) The first removal gas and the second removal gas may possess the same molecular structure. Further, the second removal gas and the reactant gas may possess the same molecular structure. Further, the first removal gas, the second removal gas, and the reactant gas may possess the same molecular structure. Thus, two or more of the first removal gas supply system, a second removal gas supply system, and the reactant gas supply system may be unified. Therefore, the apparatus configuration may be simplified.
(c) The first removal gas and the second removal gas may possess different molecular structures. Further, the second removal gas and the reactant gas may possess different molecular structures. Further, the first removal gas, the second removal gas, and the reactant gas may possess different molecular structures. Thus, gases with different reactivities may be distinctly utilized in two or more of procedure a2, procedure b2, and procedure d. Therefore, promotion or inhibition of modification in the process layer 152, the first layer 154, or the underlying film may be controlled.
(d) It is desirable to make an exposure amount of the second removal gas to the wafer 200 in procedure d greater than an exposure amount of the first removal gas to the wafer 200 in procedure a2. This enhances likelihood of the second removal gas reaching the depth side of the recess. Further, reaction between the second removal gas and the first modified layer 150 becomes easier to occur. Therefore, the removal of the first modified layer 150 progresses more sufficiently even at the depth side of the recess. Therefore, this facilitates uniform processing over the entire recess.
(e) It is desirable to make the exposure amount of the second removal gas to the wafer 200 in procedure d greater than an exposure amount of the reactant gas to the wafer 200 in procedure b2. This enhances the likelihood of the second removal gas reaching the depth side of the recess. Further, the reaction between the second removal gas and the first modified layer becomes easier to occur. Therefore, the removal of the first modified layer 150 progresses more sufficiently even at the depth side of the recess. Therefore, this facilitates uniform processing over the entire recess.
(f) In procedure a2, it is desirable to replace at least a portion of first functional groups on the wafer 200, which constitute at least a portion of the first modified layer 150, with second functional groups exhibiting higher reactivity to the process gas than the first functional groups. In procedure c, it is desirable to replace at least a portion of the second functional groups with third functional groups, which constitute at least a portion of the second modified layer 158 and possess lower reactivity to the process gas than the second functional groups. This replacement enables the removal of the first modified layer 150.

### (Modification 3)

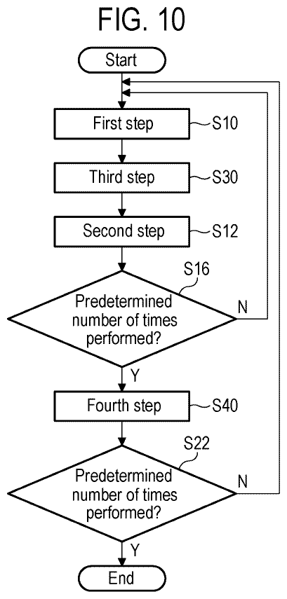

As illustrated in the process sequence of FIG. 10, after executing the first, third, and second steps a predetermined number of times, the fourth step S40 is executed. This sequence is repeated a predetermined number of times until the process is terminated. In this modification 3, the second removal gas is a gas that removes at least a portion of the first modified layer 150 and at least a portion of the second modified layer 158.

### (A) Effects of Modification 3

Even in this modification, at least some of the effects of the above-described embodiments and modifications 1 and 2 may be obtained. Further, the present modification obtains one or more of the following effects.
(a) As described in Modification 1, it is possible to more precisely control the distribution of one or both of the first and second modified layers within the pattern. In addition, as described in modification 2, uniformity of processing within the area of the wafer 200 where processing is intended to progress may be improved through the fourth step.

### Other Embodiments of Present Disclosure

The embodiments of the present disclosure are specifically described above. However, the present disclosure is not limited to the above-described embodiments, and may be changed in various ways without departing from the gist of the present disclosure.

For example, the above-described embodiments described cases where film formation is performed in procedure b, but the present disclosure is not limited thereto. By utilizing the technique of the present disclosure, it is possible to control the area of the wafer 200 where processing is likely to progress, or is inhibited. For example, the technique of the present disclosure may also be applied to perform etching on a film on the wafer 200 in procedure b. In such cases, distribution of one or both of the first modified layer 150 and the second modified layer 158 may be controlled to regulate areas where etching is likely to progress, or is inhibited.

It is desirable to prepare recipes used for each processing individually based on the processing contents and to record and store them in the memory 121c via an electrical communication line or the external memory 123. Then, when initiating each processing, it is desirable for the CPU 121a to select an appropriate recipe from among the multiple recipes recorded and stored in the memory 121c based on the processing contents. This allows for the reproducible formation of various film types, compositions, film qualities, and film thicknesses on a single substrate processing apparatus. Further, it reduces the burden on operators, minimizes the risk of operational errors, and enables quick initiation of each processing.

The aforementioned recipes may not be restricted to a case of preparing them by creating new recipes, but may also be prepared by modifying existing recipes already installed in the substrate processing apparatus, for example. When modifying recipes, the modified recipes may be installed in the substrate processing apparatus via an electrical communication line or a recording medium containing the recipes. Further, existing recipes already installed in the substrate processing apparatus may be directly modified by operating the input/output device 122 of the existing substrate processing apparatus.

In the above-described embodiments, an example of forming a film by using a batch-type substrate processing apparatus capable of processing multiple substrates at once is described. The present disclosure is not limited to the above-described embodiments, and for example, may be suitably applied even when forming a film by using a single-wafer type substrate processing apparatus capable of processing one or several substrates at once. Further, in the above-described embodiments, an example of forming a film by using a substrate processing apparatus equipped with a hot-wall type process furnace is described. The present disclosure is not limited to the above-described embodiments, and may also be suitably applied when forming a film using a substrate processing apparatus equipped with a cold-wall type process furnace. Further, in the above-described embodiments, an example of activating gases by heat or plasma is described. However, the present disclosure is not limited to this. For example, the present disclosure may also be suitably applied when gases are activated by irradiating the gases with electromagnetic waves using a lamp or other sources. Even when using such a substrate processing apparatus, it is possible to perform each processing using the same processing procedures and processing conditions as in the above-described embodiments and modifications, and to achieve the same effects as the above-described embodiments and modifications.

The above-described embodiments and modifications may be used in combination as appropriate. The processing procedures and processing conditions at this time may be the same as the processing procedures and processing conditions in the above-described embodiments and modifications, for example.

According to the present disclosure in some embodiments, it is possible to control areas of a substrate where processing is likely to progress and areas of the substrate where the processing is inhibited.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
performing a first step and a second step a predetermined number of times,
wherein the first step includes performing a predetermined number of times:
(a1) supplying a first modifying gas to the substrate to form a first modified layer on at least a portion of the substrate; and
(a2) supplying a first removal gas to the substrate to remove a portion of the first modified layer from the substrate, and
wherein the second step includes performing, after the first step, a predetermined number of times:
(b1) supplying a process gas to the substrate to preferentially process an area where the first modified layer is not formed over an area where the first modified layer is present; and
(b2) supplying a reactant gas to the substrate.

2. The method of claim 1, wherein the first removal gas and the reactant gas are gases with a same molecular structure.

3. The method of claim 1, wherein the first removal gas and the reactant gas are gases with different molecular structures.

4. The method of claim 1, wherein an exposure amount of the first removal gas to the substrate in (a2) is smaller than an exposure amount of the reactant gas to the substrate in (b2).

5. The method of claim 1, further comprising performing a third step after the first step and before the second step,
wherein the third step includes (c) supplying a second modifying gas to the substrate to form a second modified layer on at least a portion of the area of the substrate where the first modified layer is not formed.

6. The method of claim 5, wherein an exposure amount of the second modifying gas to the substrate in (c) is smaller than an exposure amount of the first modifying gas to the substrate in (a1).

7. The method of claim 5, wherein a molecular structure of the second modifying gas is the same as a molecular structure of the first modifying gas.

8. The method of claim 1, wherein the second step is performed a plurality of times, and
wherein the method further comprises performing a fourth step including performing, after performing the second step a predetermined number of times, (d) supplying a second removal gas to the substrate to remove at least a portion of the first modified layer from the substrate.

9. The method of claim 5, further comprising, after performing the first step, the third step, and the second step a predetermined number of times, (d) supplying a second removal gas to the substrate to remove at least a portion of the first modified layer and at least a portion of the second modified layer from the substrate.

10. The method of claim 8, wherein a molecular structure of the second removal gas is the same as a molecular structure of the first removal gas.

11. The method of claim 8, wherein an exposure amount of the second removal gas to the substrate in (d) is greater than an exposure amount of the first removal gas to the substrate in (a2).

12. The method of claim 8, wherein a molecular structure of the second removal gas is the same as a molecular structure of the reactant gas.

13. The method of claim 8, wherein an exposure amount of the second removal gas to the substrate in (d) is greater than an exposure amount of the reactant gas to the substrate in (b2).

14. The method of claim 1, wherein the formation of the first modified layer in (a1) includes formation of a first functional group on the substrate, and
wherein the removal of the first modified layer in (a2) includes replacing a portion of the first functional group on the substrate with a second functional group with a higher reactivity than the first functional group in relation to the process gas.

15. The method of claim 1, wherein (1) or (2) below is satisfied:
(1) the first modifying gas and the process gas contain a halogen element; and
(2) the first modifying gas and the process gas are an organic compound or contain an organic ligand.

16. The method of claim 1, wherein in the second step, a film that contains a predetermined element, which is contained in the process gas, as a main constituent element is formed on the substrate, and
wherein (a1) is performed under a condition where a substance containing the predetermined element is not formed on the substrate.

17. The method of claim 1, wherein the first removal gas includes a gas activated by plasma.

18. A method of manufacturing a semiconductor device, comprising the method of claim 1.

19. A substrate processing apparatus, comprising:
a first modifying gas supply system that supplies a first modifying gas to form a first modified layer on at least a portion of a substrate;
a first removal gas supply system that supplies a first removal gas to remove a portion of the first modified layer from the substrate;
a process gas supply system that supplies a process gas to preferentially process an area where the first modified layer is not formed over an area where the first modified layer is present;
a reactant gas supply system that supplies a reactant gas; and
a controller configured to be capable of controlling the first modifying gas supply system, the first removal gas supply system, the process gas supply system, and the reactant gas supply system, so as to perform a process of performing a first step and a second step a predetermined number of times,
wherein the first step includes performing a predetermined number of times:
(a1) supplying the first modifying gas to the substrate; and
(a2) supplying the first removal gas to the substrate, and
wherein the second step includes performing, after the first step, a predetermined number of times:
(b1) supplying the process gas to the substrate; and
(b2) supplying the reactant gas to the substrate.

20. A non-transitory computer-readable recording medium storing a program that causes, by a computer, a substrate processing apparatus to execute a process comprising performing a first step and a second step a predetermined number of times,
wherein the first step includes performing a predetermined number of times:
(a1) supplying a first modifying gas to a substrate to form a first modified layer on at least a portion of the substrate; and
(a2) supplying a first removal gas to the substrate to remove a portion of the first modified layer from the substrate, and
wherein the second step includes performing, after the first step, a predetermined number of times:
(b1) supplying a process gas to the substrate to preferentially process an area where the first modified layer is not formed over an area where the first modified layer is present; and
(b2) supplying a reactant gas to the substrate.
